(19) United States
(12) Patent Application Publication
(10) Pub. No.: US 2018/0253632 A1
(43) Pub. Date: Sep. 6, 2018

(54) CONNECTABLE SMART LABEL OR TAG, AND METHODS OF MAKING AND CONNECTING THE SAME

(71) Applicants: David ULAND, Granville, OH (US); Patricia BRITTON, New Freedom, PA (US); Peter FISCHER, Mountain View, CA (US); Aditi CHANDRA, Los Gatos, CA (US)

(72) Inventors: David ULAND, Granville, OH (US); Patricia BRITTON, New Freedom, PA (US); Peter FISCHER, Mountain View, CA (US); Aditi CHANDRA, Los Gatos, CA (US)

(73) Assignee: Thin Film Electronics ASA, Oslo (NO)

(21) Appl. No.: 15/710,730

(22) Filed: Sep. 20, 2017

Related U.S. Application Data
(60) Provisional application No. 62/466,910, filed on Mar. 3, 2017.

(51) Int. Cl. G06K 19/07; H01L 23/544; H01L 23/00

(52) U.S. Cl. CPC G06K 19/0723; H01L 23/544; H01L 2223/54446; H01L 24/06; H01L 24/29

(57) ABSTRACT

A security and/or identification device including an integrated circuit and an antenna or a battery, and methods of manufacturing and using the same, are disclosed. The integrated circuit is on a substrate to be applied, affixed or attached to a package or container, and includes a set of connection pads electrically connectable to an external component, and a memory storing a unique identification number. The antenna or battery may be on the same or a different substrate. The antenna receives a first wireless signal, transmits a second wireless signal, and enables the integrated circuit to extract power from the first wireless signal. The battery provides power to the integrated circuit. The connection pads may be electrically connectable to one or more sensing lines, and the integrated circuit may further include a continuity sensor configured to determine a continuity state of the package/container.

### CROSS REFERENCE TO RELATED APPLICATION(S)

This application claims the benefit of U.S. Provisional Patent Application No. 62/466,910, filed on Mar. 3, 2017, incorporated herein by reference as if fully set forth herein.

### FIELD OF THE INVENTION

The present invention generally relates to the field(s) of product security and authentication. More specifically, embodiments of the present invention pertain to an electronic tag and/or device (which may communicate wirelessly) that is connectable to one or more additional components, such as an antenna, sensor, battery, display and/or switch, and methods of manufacturing, connecting, and using the same.

### DISCUSSION OF THE BACKGROUND

Wireless communication tags, such as the OpenSense security tags commercially available from Thin Film Electronics ASA, include labels with electronics printed or otherwise formed thereon that detect whether a bottle or package has been opened and communicate the continuity state are NFC (near field communication) or RF (radio frequency) protocols. This product is being evaluated and accepted for instance in the packaging industry.

In the packaging industry, there are thousands of different package types. However, on a commercial scale, it is difficult or impossible to tailor a different wireless communication tag for each different type, shape and size of package. Furthermore, current solutions generally protect only one interface (e.g., one side of a package such as a carton), which is insufficient for many applications, such as packaging types with more than one interface between separable parts (e.g., a box with separable flaps on the top and bottom).

Printing items such as artwork or text on containers such as cartons has been long known. However, high-speed printing of electrical structures such as antennas on packaging such as cartons has only relatively recently become possible.

A challenge facing the packaging industry is finding a shape for a sense line or other security feature that protects each opening of the package. For example, a package such as a box or carton typically has at least 2-3 openings at the interfaces between separable parts. The challenge to do so at high speed is even greater.

WO 2016/066925 discloses an anti-counterfeiting NFC device to ensure the authenticity of the contents of a bottle. The hybrid NFC tag of WO 2016/066925 includes components on a plastic substrate and a paper-based substrate, coupled to each other by a transformer formed by a first winding arranged on the plastic substrate and a second winding arranged on the paper-based substrate. The paper-based substrate may typically be in strip form and include a sacrificial zone through conductive tracks connecting the components of the paper-based substrate. The paper-based substrate may comprise a driver microcircuit connected to the second winding, and the plastic substrate may comprise an antenna coil connected to the first winding. The paper-based substrate may comprise an impedance connected to the second winding by a conductor track crossing the sacrificial area, and the plastic substrate may include a driver microcircuit and an antenna coil connected to the first winding. The impedance may be a short circuit. The driver microcircuit can be configured to be powered by the antenna coil and include functions for transmitting information and cryptographic functions, the components of the NFC tag being chosen so that the rupture of the sacrificial area lowers the power supply received by the microcircuit to a level insufficient to supply cryptographic functions, but at a still sufficient level to power the transmission functions. However, loss of additional functionality such as cryptographic functions is undesirable in many security and/or identification devices, and there is a need for a security and/or identification device that retains full functionality at all times while still ensuring the authenticity of the contents of the package or container to which the security and/or identification device is attached, affixed and/or associated.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

There is a need for a generic, standard or universal security or ID tag or device that facilitates or enables sensing the continuity state of a package or container having 2 or more interfaces between separable parts of the package or container, and that can be attached to packages at high speed. Thus, the present invention generally relates to the field(s) of product security and authentication. More specifically, the present invention relates to a standard communication device (e.g., a wireless or battery-operated security tag) with two open circuit endpoints (e.g., connection terminals), and methods of manufacturing and using such devices (e.g., attaching the circuit endpoints to a sense line that may be printed on a container or product packaging).

Thus, in one aspect, the present invention relates to an electronic security and/or identification (ID) tag and/or device. The tag and/or device may communicate wirelessly, or alternatively, may include a display. The present security and/or ID tag and/or device includes a first substrate, an integrated circuit on the substrate, and a component selected from an antenna and a battery on the same substrate or a different substrate. The first substrate is configured to be applied, affixed or attached to a package or container. The integrated circuit includes (i) a first set of connection pads electrically connected to the integrated circuit and configured to be electrically connected to another component external to the integrated circuit and the first substrate, and (ii) a memory storing a unique identification number for the security and/or identification device. The antenna is configured to (i) receive a first wireless signal and optionally transmit or broadcast a second wireless signal and (ii) enable the integrated circuit to extract power from the first wireless signal. The battery provides power to the integrated circuit. The present security and/or identification device may further comprise an adhesive on the substrate (e.g., for securing or affixing the integrated circuit to the package or container).

In exemplary embodiments, the integrated circuit comprises a continuity sensor electrically connected to the first set of connection pads, configured to determine a continuity state of the package or container. In such embodiments, the memory generally includes one or more bits configured to store a value corresponding to the continuity state of the container or package. In further embodiments, the integrated circuit may comprise one or more additional sets of connection pads electrically connected to the integrated circuit, and the combined first set of connection pads and additional set(s) of connection pads are configured to be electrically connected to a plurality of sensing lines on the package or container.

In various embodiments of the present security and/or identification device, the component comprises the antenna. In one case, the antenna is on a common substrate (e.g., the same substrate as the integrated circuit). In such a case, the security and/or identification device may further comprise a strap electrically connecting an inner end of the antenna to a location on the substrate external to the antenna.

In another case, the antenna is on a different substrate from the integrated circuit. In such a case, the antenna may include a second set of connection pads, and the integrated circuit includes first and second bond pads configured to be electrically connected to the second set of connection pads. In this manner, the integrated circuit functions as a strap, electrical bridge or other electrical connection connecting the inner and outer ends of the antenna. Such a configuration also enables the antenna to consist of a single metal layer.

In some embodiments of the present security and/or identification device, invention, the component comprises the battery. In further embodiments, the security and/or identification device further comprises a display on the same or different substrate as the battery and/or integrated circuit. In some embodiments, the battery and the display are on a common substrate. The display is typically electrically connected to both the battery and the integrated circuit. The integrated circuit may be configured to provide data and/or one or more instructions to the display.

Various embodiments of the present security and/or identification device may further comprise a further component, such as a switch or a sensor other than a continuity sensor, on the same or different substrate as the integrated circuit and/or the antenna or battery. In general, the further component is electrically connected to the integrated circuit. When the third component is on a substrate other than the integrated circuit substrate, the integrated circuit comprises a set of unique connection pads to be electrically connected to the further component.

When the security and/or identification device includes an antenna (and thus is able to communicate wirelessly), the device may be a near field and/or radio frequency (RF) security and/or identification device.

In various embodiments, the integrated circuit includes one or more printed layers and/or one or more thin films. In further embodiments, the integrated circuit may comprise a plurality of printed layers. For example, the integrated circuit may comprise one or more printed layers and one or more thin films.

In additional or alternative embodiments, the substrate(s) on which the integrated circuit, the antenna, the battery and/or the further component are formed may comprise a plastic or a metal foil. In some embodiments, the substrate is flexible and/or can withstand a processing temperature of up to 200° C.

In another aspect, the present invention relates to a method of manufacturing a security and/or identification device, comprising forming an integrated circuit on a first substrate configured to be applied, affixed or attached to a package or container, and forming an antenna or a battery on the first substrate or a second substrate. As for the present device or tag, the integrated circuit includes (i) a first set of connection pads electrically connected to the integrated circuit and configured to be electrically connected to a component external to the integrated circuit and the first substrate, and (ii) a memory storing a unique identification number for the security and/or identification device. The antenna is configured to (i) receive a first wireless signal and optionally transmit or broadcast a second wireless signal and (ii) enable the integrated circuit to extract power from the first wireless signal, and the battery provides power to the integrated circuit.

In some embodiments of the present method, the integrated circuit comprises a continuity sensor electrically connected to the first set of connection pads, configured to determine a continuity state of the package or container. In such embodiments, the memory may include one or more bits configured to store a value corresponding to the continuity state of the container or package. Furthermore, forming the integrated circuit may comprise forming one or more additional sets of connection pads electrically connected to the integrated circuit and configured to be electrically connected to a plurality of sensing lines on the package or container.

In various embodiments of the present method, the security and/or identification device comprises the antenna. Thus, the present method may comprise forming the antenna on the first substrate (i.e., the same substrate as the integrated circuit). In such embodiments, the method may further comprise forming a strap electrically connecting an inner end of the antenna to a location on the first substrate external to the antenna.

Alternatively, the method may comprise forming the antenna on the second (i.e., a different) substrate. In such embodiments, forming the antenna may include forming a second set of connection pads on the second substrate, and individual ones of the second set of connection pads may be electrically connected to inner and outer ends of the antenna, respectively. As a result, forming the integrated circuit may include forming first and second bond pads (e.g., in an uppermost or lowermost layer of metallization) configured to be electrically connected to the second set of connection pads. Similar to the present security and/or identification device, in such a configuration, the integrated circuit functions as a strap connecting the inner end of the antenna and the outer end of the antenna. In addition, the antenna can consist of a single metal layer, and forming the antenna may consist of forming a metal layer on the substrate, and etching the metal layer to form the antenna. Alternatively, forming the antenna may comprise printing a metal ink on the substrate in a pattern corresponding to the antenna.

In other embodiments of the present method, the security and/or identification device comprises the battery. Such embodiments may further comprise forming a display on the first substrate, the second substrate or a third substrate. The display is electrically connected to the battery and the integrated circuit, and the integrated circuit is generally configured to provide data and/or one or more instructions to the display. In one example, the method comprises forming the battery and the display on a common substrate.

In further embodiments of the present method, forming the display may comprise forming a photoactive layer on the same or different substrate, and forming a plurality of electrodes thereto (at least one of which may be transparent). When the photoactive layer and the electrodes are not formed on a transparent substrate (or transparent window in the substrate), the method may further comprise forming a transparent window over the photoactive layer and the electrodes. In addition, forming the battery may comprise forming a first current collector layer, a cathode or anode thereon, an electrolyte layer on the cathode or anode, the other of the cathode or anode on the electrolyte layer, and a second current collector layer on the other of the cathode or anode. The layers of the battery may be formed by printing and/or thin film processing.

In various embodiments of the present method, the method further comprises depositing an adhesive on the first substrate and/or forming a switch and/or a sensor (other than the continuity sensor) on the first substrate, the second substrate or a third substrate. The switch and/or other sensor is electrically connected to the integrated circuit. In some examples, the method comprises forming the switch and/or other sensor on a substrate other than the first substrate, in which case the method may further comprise forming a second set of connection pads electrically connected to the integrated circuit and configured to be electrically connected to the third external component.

In other or further embodiments of the present method, forming the integrated circuit comprises printing one or more layers of the integrated circuit. For example, forming the integrated circuit may comprises printing a plurality of layers of the integrated circuit. Additionally or alternatively, the method may further comprise forming one or more additional layers of the integrated circuit by thin film processing. In one embodiment, forming the integrated circuit comprises printing all of the layers of the integrated circuit. In other embodiments, forming the integrated circuit comprises printing one or more layers of the integrated circuit and forming the remaining layers of the integrated circuit by thin film processing.

As for the present security and/or identification device, the first substrate (as well as the second and/or third substrate[s]) in the present method may comprise a plastic or a metal foil. For example, the first substrate may be flexible and may withstand a processing temperature of up to 200° C.

In a further aspect, the present invention relates to a package or container including first and second separable parts with an interface between the separable parts, with the security and/or identification device discussed above thereon. The integrated circuit and the antenna or battery are on one of the first and second separable parts of the package or container. In addition, a sensing line is on the first and second separable parts of the package or container and in or over an interface between the first and second separable parts. The package or container may comprise a box, a tray with a lid, a bottle, an envelope or a bag.

In various embodiments, the package or container comprises multiple sealed or closed compartments, the integrated circuit comprises a plurality of sets of connection pads, the sensing line comprises a plurality of the sensing lines, and each of the plurality of sensing lines extends over a unique one of the multiple sealed or closed compartments.

In an even further aspect, the present invention relates to a method of determining a continuity state of a package or container that includes connecting connection pads of an integrated circuit on a substrate (as described herein) to a sensing line on first and second separable parts of the package or container and over an interface between first and second separable parts of the package or container, and sensing the continuity state of the package or container using the integrated circuit and a continuity sensor therein. The integrated circuit may be electrically connected to an antenna or a battery. The sensing line is configured to sense or determine a continuity state of a package or container on which the security and/or identification device is placed or to which the security device is fixed or adhered.

In various embodiments, placing the integrated circuit on the container or package includes adhering or affixing the integrated circuit to the container or package. For example, adhering the integrated circuit to the container or package may include applying an adhesive on the substrate on which the integrated circuit is formed, and pressing the substrate to the container or package.

The present invention advantageously enables a manufacturer of integrated circuits for sensing a continuity state of a package or container to make and/or manage a reduced number of products, and enables a packager to electronically protect any size or shape of carton, container or other packaging. This reduces the lead time for providing packaged products to a customer since a standard and/or uniformly-sized integrated circuit and power supply source (e.g., antenna or battery) can be stocked by the packager, and reduces the cost and complexity of designing a new integrated circuit and power supply source for each size and/or shape of container. These and other advantages of the present invention will become readily apparent from the detailed description of various embodiments below.

### BRIEF DESCRIPTION OF THE DRAWINGS

FIG. 1 shows an exemplary wireless security tag in accordance with one or more embodiments of the present invention.

FIGS. 2A-B show an alternative exemplary wireless security tag in accordance with one or more embodiments of the present invention.

FIGS. 3A-B show an exemplary connection between connection pads of the wireless security tag of FIGS. 1-2 and terminals of a printed sense line on a different substrate in accordance with one or more embodiments of the present invention.

FIGS. 4A-C show an exemplary security tag connected to a customized sensing line on a package or container in accordance with one or more embodiments of the present invention.

FIGS. 5A-C show an exemplary multi-compartment container having an alternative security tag with multiple continuity sensors therein in accordance with one or more alternative embodiments of the present invention.

FIG. 6 shows exemplary functional modules or units for the present security or ID tag or device in accordance with embodiments of the present invention.

FIGS. 7A-B show an exemplary security and/or ID tag or device with a display in accordance with one or more embodiments of the present invention.

FIG. 8 shows an exemplary integrated circuit for use in the present wireless security or ID tag or device.

FIG. 9 shows a flow chart for an exemplary method of manufacturing and optionally using the present security and/or ID device in accordance with one or more embodiments of the present invention.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures and components have not been described in detail so as not to unnecessarily obscure aspects of the present invention. Furthermore, it should be understood that the possible permutations and combinations described herein are not meant to limit the invention. Specifically, variations that are not inconsistent may be mixed and matched as desired.

In addition, for convenience and simplicity, the terms “part,” “portion,” and “region” may be used interchangeably but these terms are also generally given their art-recognized meanings. Also, unless indicated otherwise from the context of its use herein, the terms “known,” “fixed,” “given,” “certain” and “predetermined” generally refer to a value, quantity, parameter, constraint, condition, state, process, procedure, method, practice, or combination thereof that is, in theory, variable, but is typically set in advance and not varied thereafter when in use.

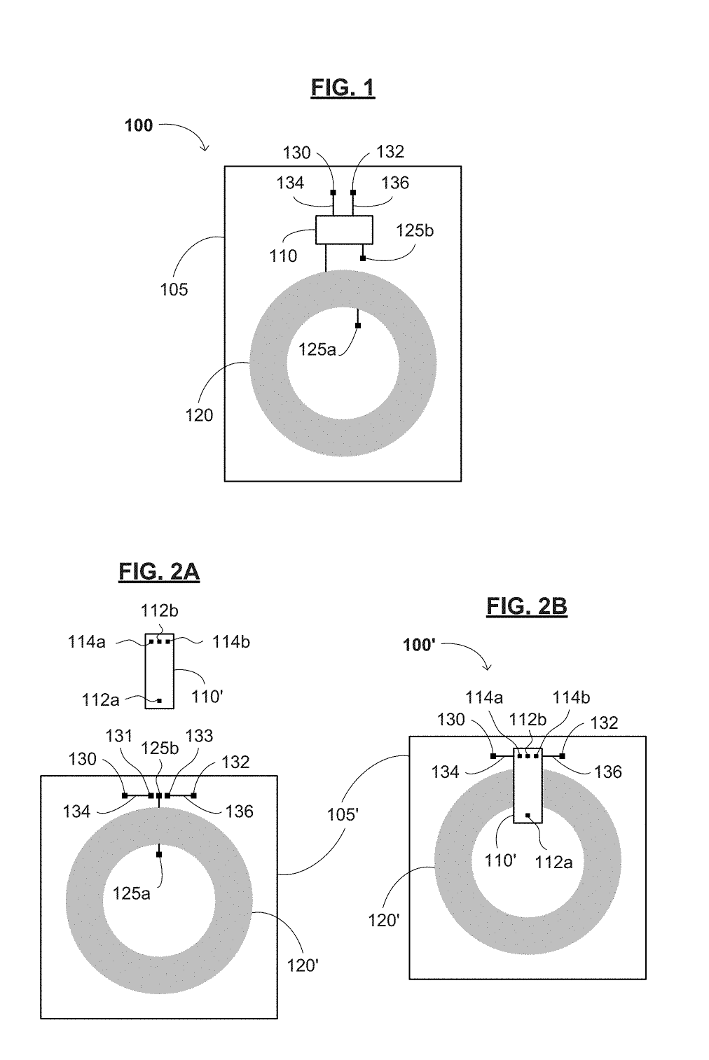

The present wireless security or ID device is produced without sense lines, as shown in FIG. 1. The wireless security or ID device is then coupled to a printed sense loop on the container or package, which means that it can be used for almost any type of package without modification. However, there is a need to create an ohmic contact to electrically connect the printed sense loop and the antenna and/or integrated circuit. This is a challenge that can be solved in several ways.

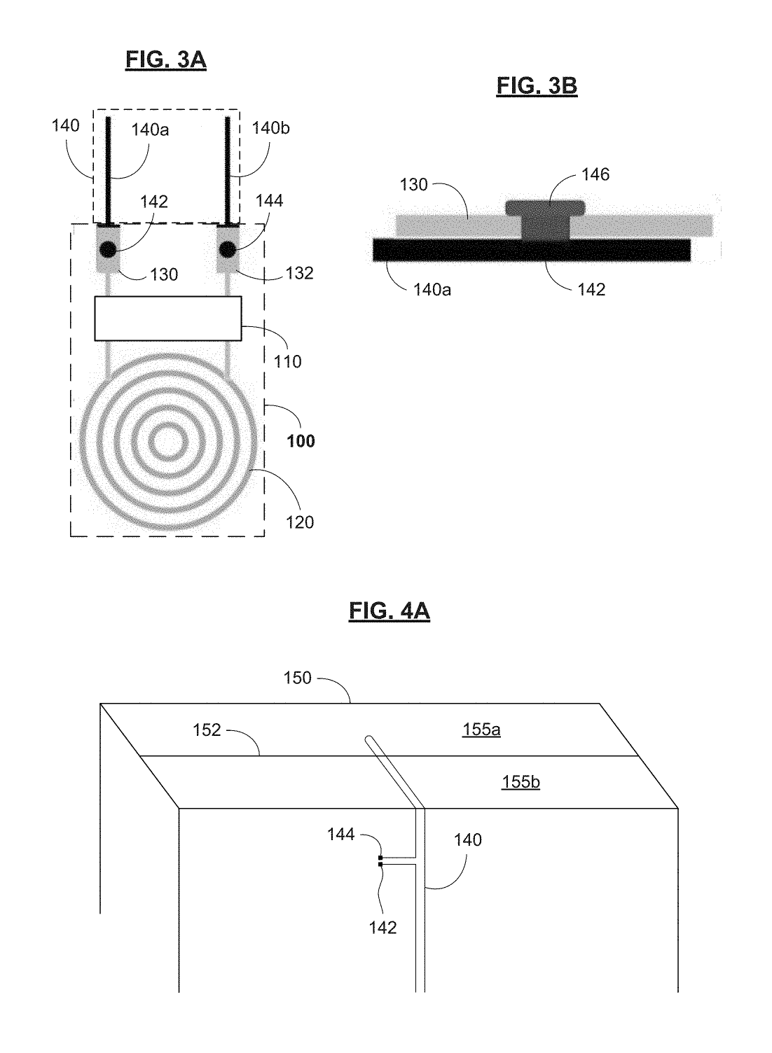

One objective of the present invention is to connect a wireless security device to a printed sense loop. Some commercially-available wireless security devices include an antenna made of aluminum. One challenge is that aluminum oxidizes rapidly, which makes it hard to create an ohmic contact between the connection points of the antenna and the printed sense loop. One solution is to use a conductive ink or adhesive to attach the antenna and/or integrated circuit of the wireless security device to the printed sense line, and sinter it with a laser as shown in FIGS. 3A-B. Another solution is to use different antenna materials that do not oxidize easily (e.g., copper, graphene, etc.). A third solution is to protect the aluminum antenna or connection point (terminal) using a protective coating or similar oxygen barrier.

One way to implement the present wireless security device in packages and containers is to attach the antenna and/or integrated circuit to the sense line in a packaging process/manufacturing line using a conductive glue, laser welding or similar attachment technique. The printed loop that detects the continuity state of the package (e.g., whether the package is opened or sealed) can typically be printed using a conductive ink (e.g., silver or other metal, carbon, a conductive polymer, etc.). Another objective is to use sensors in or in proximity to the conductive sense loop, thus using sensor data to indicate an opened package or container instead of a physical tear action (e.g., a broken sense line).

Exemplary Connectable Security Tags with a Wireless Communication Device and a Continuity Sensor Thereon

The present invention relates to an electronic security tag and/or device with a sensor configured to detect an opened or tampered state of a package or container to which the tag and/or device is attached. In one embodiment, the security tag or device communicates wirelessly (e.g., with an NFC or RF reader). In other embodiments, the security tag or device includes a display and a battery. The security device generally includes an integrated circuit on or over a substrate, an antenna or display on the same or a different substrate, and a first set of terminals electrically connected to the integrated circuit (and, optionally, the antenna or display). The first set of terminals is configured to be electrically connected to a sense line or loop on a package or container. The antenna is configured to receive a first wireless signal (e.g., from the reader) and/or transmit or broadcast a second wireless signal (e.g., from the integrated circuit). The display is configured to display an indicator indicating a continuity state of a package or container on which the security device is placed or to which the security device is fixed or adhered. The integrated circuit is configured to determine a continuity state of the package or container and either (i) process the first wireless signal and/or information therefrom and generate the second wireless signal and/or information therefor, or (ii) indicate the continuity state of the package or container using the display. A receiver and/or transmitter may be integrated into the integrated circuit (e.g., when the security device includes an antenna).

Thus, the security device is connectable to a sensing line on the package or container. The sensing line is generally configured to sense a continuity state of the package or container on or in which the sensing line has been formed (e.g., printed). In one embodiment, the integrated circuit includes a first set of terminals to which the sensing line is connected. The first set of terminals is different from a second set of terminals that are electrically connected to the antenna or display. In an alternative embodiment, the antenna is also electrically connected to the first set of terminals.

In some embodiments, the present tag and/or device is a generic wireless security tag with a generic antenna connected thereto, and a mechanism for connecting the generic wireless security tag to a continuity sensor on a separate substrate (e.g., the package or container). However, the invention is not so limited. Connecting the generic OS tag to a continuity sensor is one of several possible components that can be made more easily or efficiently on a separate substrate. Displays, additional sensors, batteries, and switches (e.g., to connect/disconnect the tag and/or device to another component) can be connected in the same way (e.g., using a set of terminals electrically connected to an integrated circuit).

In fact, the antenna may also be separately connectable to the integrated circuit (generally through a second set of terminals different from the first set of terminals). However, in some embodiments, at least one of the separately connectable components is on the same substrate as the integrated circuit (the antenna is preferred, in typical embodiments). The separately connectable component may be electrically connected to the integrated circuit and/or antenna using any of a variety of different mechanisms (e.g., capacitive, inductive, and several different kinds of ohmic connections).

Thus, in one aspect, the present invention relates to a generic, standard or universal security tag including an integrated circuit (IC) and a second component (generally either [1] an antenna or [2] a battery and an optional display) on one substrate, with a set of terminals configured to electrically connect the IC to a third component on a different substrate. In a second aspect, the present invention relates to a generic, standard or universal security tag on a first substrate with a plurality of sets of terminals, each connected to a functionally different component on a plurality of different substrates. In this aspect, at least one of the different components is an antenna or battery, and another is a sensor, display, or switch.

In any case, the present invention provides a fully secure wireless or display-based security solution for any shape of package, container or carton. The solution does not require line of sight, so it does not interfere with any graphics on the package, container or carton. The present security tag/device can assist with use cases such as return fraud, in-store tampering of cartons, and consumer protection. The present security tag/device can also help with consumer engagement (e.g., to ensure that the consumer opens the package, container or carton correctly). Some commercially available devices offering a 2-state solution do not always work if the container or package is not opened as intended by the manufacturer or packager.

The present invention is also applicable to flexible packaging. Thus, in various embodiments, the antenna and/or the integrated circuit can be on a substrate that comprises paper, a glass/polymer laminate, a paper/polymer laminate, a high temperature polymer, a metal foil, or a combination thereof. When the substrate comprises the high temperature polymer, the high temperature polymer may comprise a polyimide, a polyethersulfone, a polyethylene naphthalate (PEN), or a polyether ether ketone (PEEK). Alternatively, when the substrate comprises a metal foil, the metal foil may comprise aluminum, stainless steel or copper.

In summary, the present invention comprises a security and/or identification tag (e.g., an inlay and/or chip) with a decoupled sense line, on different substrates and/or materials. The present invention allows the packager to create the sense line in any way that makes sense (e.g., printing on any of a variety of substrates with any of a variety of materials by any of a variety of techniques).

The sense line in the present security device and/or tag is effectively made with an open circuit. The circuit endpoints can be printed with a wide pad (for ease of placement tolerance) and optionally a via hole, and in some cases with isotropic or anisotropic conductive adhesive on the underside that can be pattern-printed. The via functions as a conduit connecting the integrated circuit to the printed sense trace(s) or line(s). The sense line can be printed over all of the openings of the container (e.g., the three interfaces or openings in a carton), so any side of the carton that is opened changes the state of the continuity sensor and indicates an open package. This type of via or through-hole construction is common in the printing/die cutting industry, but to the best of the inventors' knowledge, it has not been used to attach a wireless or display-based security tag to a printed sense line.

For example, attachment of the terminals connected to the IC could be made with an anisotropic pressure-sensitive adhesive (PSA) and/or a heat-activated conductive adhesive (e.g., that electrically connects the sense lines to the terminals when heating a shrink-wrap film applied to the package or container). Alternatively, the sense line may be coupled to the IC using a capacitive coupling approach (e.g., an inductor printed over an interface of the container that is also capacitively coupled to the antenna of the present security tag/device). The present security tag/device has the potential to help the sense line to break more efficiently and/or effectively on the container, and makes both processes (printing on the container and inlay/tag manufacturing) more efficient.

FIG. 1 shows an exemplary wireless security tag/device 100, including an integrated circuit (IC) 110, an antenna 120, antenna terminals 125a-b, and IC terminals 130 and 132 on a substrate 105. Traces 134 and 136 electrically connect the IC terminals 130 and 132 to the IC 110 (e.g., to pads on the IC 110). The antenna terminals 125a-b are for a strap to electrically connect the inner end of the antenna 120 to a location outside the antenna 120.

The substrate 105 for the wireless security tag/device 100 of FIG. 1 is rectangular or substantially rectangular, although the substrate 105 may have another shape suitable for a particular application (e.g., such as t-shaped, oval, elongated, rectangular or other quadrilateral [with or without rounded corners], tapered, or as otherwise described herein). In exemplary embodiments, the substrate 105 may comprise paper, a polymer (e.g., a high temperature polymer such as polyethylene naphthalate [PEN] or polyethylene terephthalate [PET], nylon, polyvinyl alcohol and copolymers thereof [e.g., ethylene-vinyl alcohol (EVOH) copolymers], polyvinyl chloride [PVC], polypropylene [PP], polychlorotrifluoroethylene [PCFE; e.g., ACLAR® pharmaceutical packaging film, available commercially from Honeywell], polyethylene [PE; e.g., high density PE (HDPE)]), a metal layer or foil (e.g., comprising aluminum, stainless steel or copper), a laminate or other combination thereof, etc.

In exemplary embodiments, the integrated circuit 110 includes a continuity sensor (not shown) electrically connected to the traces 134 and 136. The integrated circuit 110 may further include a memory (not shown) including one or more bits configured to store a value corresponding to a continuity state of a container or package on which the substrate 105 is attached or secured. The memory may also include a plurality of bits that store identification information (e.g., a device identification number), product information, information from at least one other sensor, software instructions, etc.

In some embodiments, the integrated circuit 110 includes one or more printed layers. For example, memory bits storing information that does not change (e.g., device identification information, instructions) may be formed by printing one or more layers of the memory, similar to a read-only memory (ROM). In one example, the integrated circuit is an “all-printed” integrated circuit (i.e., all or substantially all layers are printed layers). In further embodiments, the integrated circuit 110 includes one or more thin films, as an alternative to or in combination with one or more printed layer(s). In any of these embodiments, the IC 110 can be formed directly on the substrate 105.

In various embodiments, the antenna 120 may comprise a coil, concentric rings or a plurality of loops or “rings” in a spiral. For example, the number of loop or “rings” may be from 2 to about 50, or any natural number or range of natural numbers therein. Alternatively, the shape of the antenna 120 may be a square, rectangular, oval or serpentine, and may have dimensions that match any of multiple form factors, while preserving compatibility with reader hardware (e.g., the NFC 13.56 MHz target frequency). The antenna 120 may be printed (e.g., using a printed conductor such as, but not limited to, silver from a silver paste or ink) or formed using conventional methods such as blanket deposition and etching (e.g., by sputtering or evaporating aluminum on the substrate 105 and patterning by low-resolution [e.g., 10-1,000 μm line width] photolithography and wet or dry etching).

In one embodiment, the IC 110 is formed on ends of the traces 134 and 136, the outer end of the antenna 120, and the trace to which the antenna pad 125b is connected. Alternatively, the IC 110 is built up layer by layer on the substrate 105, and the ends of the traces 134 and 136, the outer end of the antenna 120, and the trace to which the antenna pad 125b is connected are formed in contact with conductive pads on the IC 110 that are, in turn, connected to circuitry in the IC 110.

The inner end of the antenna 120 may be electrically connected to a first pad 125a, which is conventionally connected to a second pad 125b that is electrically connected to a terminal on the integrated circuit 130. In one example, a strap is formed on the underside of the substrate 105 and bonded to the pads 125a-b through vias in the substrate. Alternatively, the strap can be formed on an interposer (i.e., an insulating substrate) and bonded to the pads 125a-b through vias in the interposer or in a dielectric layer formed over the strap.

In the alternative shown in FIGS. 2A-B, the integrated circuit 110′ can function as such a strap when formed on an electrically insulating interposer (a so-called “integrated interposer”). In such embodiments, the integrated circuit 110′ includes first and second pads 112a-b (that connect to antenna pads 125a-b) and third and fourth pads 114a-b (that connect to pads 131 and 133 at the ends of traces 134 and 136 on the substrate 105′). With the exception of antenna pad 125a being on the inside of the antenna 120′ and antenna pad 125b being on the outside of the antenna 120, the various pads may be in any location as long as the first and second pads 112a-b overlap with the antenna pads 125a-b, and the third and fourth pads 114a-b overlap with the trace pads 131 and 133. FIG. 2B shows the IC 110 electrically connected to the antenna 120′ and the traces 134 and 136 through the first and second pads 112a-b and the third and fourth pads 114a-b, respectively (e.g., by soldering, a conductive paste or adhesive, etc.).

Referring now to FIG. 3A, the wireless security device 100 includes an antenna 120, an integrated circuit 110, and a set of terminals 130 and 132 for connection to a sensing line 140. The terminals 130 and 132 may be connected to pads 142 and 144 at opposite ends of the sensing line 140, for example, using a via (FIG. 3B). In one embodiment, a via or hole is punched through each of the terminals 130 and 132, and a conductive adhesive 146 is placed in the via or hole. In a further embodiment, the via or hole is also punched through the substrate 105 (FIG. 1) under or over the terminals 130 and 132, or a window or other opening is formed in the substrate 105 over the terminals 130 and 132. The wireless security device 100 with the vias or holes punched in the terminals 130 and 132 is then placed directly on the carton or other container with the traces 140a-b printed thereon. (“140a” and “140b” refer to opposite ends of a single wire on the container.) Connector pads 142 and 144 may also be printed on the container to allow for wide placement tolerance of the wireless security device 100 on the container (e.g., so that the pads 130 and 132 overlap with the pads 142 and 144). Dimensions of the sensing line 140 may vary depending on the size and/or shape of the container or package.

The exact size, shape and alignment of the vias in the pads 130 and 132 can be anything as long as the conductive adhesive 146 makes contact with both of the pads 130 and 142 (to connect the IC 110 to sensing line end 140a), and separately, both of the pads 132 and 144 (to connect the IC 110 to sensing line end 140b). Preferably, the vias are completely within the area of the pads 130 and 132. In general, the vias have width and length (area) dimensions that are no more than 80-90% of the corresponding dimensions of the pads 130 and 132. Alternatively, the vias have a maximum area dimension (e.g., width, length or diameter) that is less than the corresponding dimension of the pads 130 and 132, minus two alignment tolerances of the equipment forming the vias.

In one embodiment, the antenna 120, the pads 130 and 132, and the traces thereto are formed in a single process using a metal such as aluminum. One issue that may arise when the pads 130 and 132 comprise aluminum is securing good ohmic contacts to the pads 130 and 132. Thus, in a further embodiment, a layer comprising or consisting essentially of tin or a tin alloy (e.g., tin with one or more alloying metals or elements selected from bismuth, silver, copper, zinc, and indium) may be deposited on the aluminum pads 130 and 132, and optionally, on the traces thereto (e.g., by immersion plating or printing). When the pads 130 and 132 comprise tin-coated aluminum, silver or copper (or another solder-compatible metal or alloy), the sensing line 140 may be attached to the pads 130 and 132 by bumping or welding. Alternatively, the ink or paste may comprise palladium or a photosensitive conductive material that is cured by irradiation with light (e.g., ultraviolet light). When the ink or paste comprises palladium, the ink may comprise an aqueous or organic solution of a palladium salt or complex, and be used to print a seed layer on which a bulk metal conductor (e.g., aluminum or copper) is plated, electrochemically or electrolessly.

In another example, an ink or paste of a conductive metal such as silver or copper or other curable conductive ink may be placed in the vias and irradiated with a relatively high dose of radiation (e.g., from a laser) to sinter the metal or other conductor in the ink. Alternatively, curing may involve a so-called flash cure (e.g., using a 300 ms dose of visible light), for example using a flash-curable material available commercially from Nanocentrix. In a further alternative, an anisotropic pressure sensitive material (available commercially from 3M) can be used to join the pads 130 and 132 to the sense line ends 142 and 144. A variety of conductive adhesives may be compatible with processes and/or materials for forming the sense line 140 on the packaging or container. Thus, other materials and/or methods suitable to connect the wireless security device to a printed sense line are contemplated, and the invention is not limited to the specific materials and methods described herein.

In a further alternative to the vias in FIGS. 3A-B, the antenna 120, the pads 130 and 132, and the traces thereto are formed in a single process using a different conductive material such as carbon black, graphite, carbon nanotubes, etc. Carbon loops have sufficiently good electrical properties for formation of antennas, in which case the antenna 120 may be printed using a carbon ink. For example, one laboratory sample of a carbon-based antenna had an electrical conductance of 10⁴ siemens/cm². When the sensing line 140 also comprises printed conductive carbon, the carbon-to-carbon ohmic contact is acceptable for connecting the IC 110 to the sensing line 140. Another advantage to carbon as an antenna material is that the antenna 120 can be printed on a side of the substrate 105 opposite to that of the IC 110.

An advantage of the present approach is that the substrate 105 and IC 110 provide a relatively large amount of area or space to form the antenna 120, the traces, the vias, and the conductive adhesive 146, and allow ample room for alignment of overlapping structures with each other.

In one alternative embodiment, the antenna 120 is printed on the substrate 105, and then the IC 110 (which may be formed on a separate substrate) is placed on the antenna 120 in a manner electrically connecting the IC 110 to the antenna 120. For example, connection pads may be formed in an uppermost layer of metallization in the IC 110 and exposed through an overlying passivation, and such connection pads may be bonded to ends of the antenna 120 using any of the pad connection techniques described herein.

In any case, the IC 110 and antenna 120 may comprise materials that can tolerate a relatively high temperature (e.g., routinely up to about 400° C., and in limited excursions, up to about 600° C.), and can be generic, without many different variations to design, track, and maintain. On the other hand, the sense line 140 tends to be somewhat product- or package-specific, since it is formed on the product or package. In fact, placement and formation of the sense line 140 may be performed by an entity different from the entity or entities that manufacture the IC 110 and/or antenna 120 and/or that connect the IC 110 to the sense line 140. In general, the sense (or continuity) line 140 is relatively simple and does not require fine tolerances or tuning (e.g., such as in an RF circuit or the antenna 120). Thus, when the sense line 140 is a separate material, it can be designed and manufactured to tear easily when the package or container is opened. Consequently, it may be an advantage when the sense line 140 is not strong, and especially so when it is printed on a tearable material such as paper or a thin polypropylene film. Furthermore, separating the manufacturing processes for the sense line 140 and the antenna 120 allows different, and more specifically tailored, materials to be used for the sense line 140, as compared to the antenna 120.

In a further alternative, the sense line 140 may be formed on a substrate separate from the package or container, then the substrate with the sense line 140 thereon may be placed on and/or adhered to the package or container.

In an alternative arrangement, the sense line 140 may be capacitively coupled to the IC 110 or antenna 120. In one such arrangement, the ends of the traces to the pads 130 and 132 (the pads 130 and 132 may be omitted) may be shorted together by a further trace, and no physical connection between the sense line 140 and the pad trace from the IC 110 is made. To sense the continuity of the sense line 140, a pulse or other electrical signal can be placed on one pad or end of the pad trace, and the effect of an expected capacitive or inductive coupling can be detected on the other pad or end of the pad trace (e.g., using conventional voltage or current detection circuitry).

Such wireless contact (i.e., capacitive and/or inductive coupling) advantageously avoids any need to include a material the primary function of which is to make ohmic contact between the sense line 140 and the pads 130 and 132. Capacitive and/or inductive coupling between the sense line 140 and the IC 110 also avoids processing issues such as alignment between the pads 130 and 132 and the sense line 140, and can provide the highest-speed processing for placement of the IC 110 and antenna 120, without temperature and/or other restrictions. Thus, a smart security tag 100 with a short between the pads 130 and 132 can function as a small antenna that inductively couples with the sense line 140, which functions as a larger antenna.

In a further alternative, a similar loop-shaped trace electrically connected at both ends to the IC 110 can be capacitively and/or inductively coupled to the antenna 120. Such an alternative simplifies manufacturing of both the IC 110 and the antenna 120, and also avoids issues with placement and/or alignment of the IC 110 and the antenna 120 (see, e.g., FIG. 1B).

In one or more further embodiments, one or more additional sensors may be included on the packaging, on the substrate 105, or in the IC 110. The additional sensor(s) may be sensitive to (e.g., able to sense a continuity state of) secondary packaging such as shrink wrap on a bottle or jar, an inner (and mechanically weaker) box, etc. An additional continuity sensor may take the form of a secondary antenna inductively coupled to the antenna 120 and/or sense line 140, wherein part of the secondary antenna is on one separable part of the secondary packaging and another part of the secondary antenna is on another separable part of the secondary packaging, such that the secondary antenna is broken upon separation of the separable parts of the secondary packaging, and the sense line 140 or antenna 120 undergoes or senses an inductive change as a result. The active part of the security tag or device remains on the IC 110, rest of it is at the converting level. However, other sensors can be attached or connected to the sense line or loop 140, such that the other sensor(s) can be used to break (electrically or physically) the sensor loop 140 when the packaging is opened.

An Exemplary Security Tag with a Wireless Communication Device and Continuity Sensor on an Exemplary Sealed Container

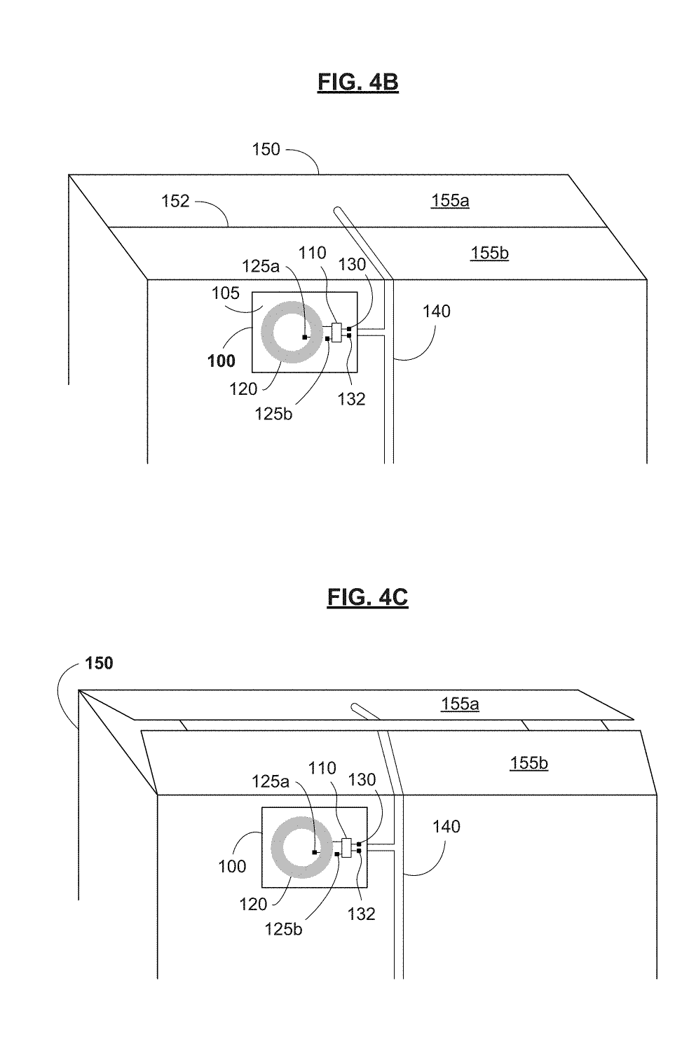

FIG. 4A shows an exemplary container 150 with a sense line 140 thereon, for use with a smart security tag on a separate substrate (see FIGS. 4B-C, for example) in accordance with one or more embodiments of the present invention. As shown in FIG. 4A, the container or package 150 includes a box with separable flaps 155a-b at one end of the box. Another set or pair of separable flaps is at an opposite end of the box (not shown). Generally, the flaps 155a-b have an interface 152 therebetween. The sense line is connected to pads 142 and 146 for subsequent attachment to the smart security tag.

Generally, the sense line pads 142 and 144 are on one of the separable parts of the container 150 (e.g., the flap 155b) or a part of the container connected thereto or integrated therewith (e.g., the front panel of the container 150), and the sensing line 140 is on both the first and second separable parts 155a-b of the container 150 and in, on or over the interface 152. In the embodiment shown, the sense line 140 is, in one configuration, the sensing line 140 is also on both the first and second separable flaps on the other side of the container 150 and in, on or over the interface between those separable flaps.

In one embodiment, the sense line 140 is printed on the outside of the container 150 after sealing the container 150. Alternatively, the sense line 140 may be printed on an adhesive tape or label, and applied to the container 150 after it has been sealed. In a further embodiment, the sense line 140 may be printed on an inside surface of the container 150 and across the ends of the flaps 155a-b at the interface 152 before it has been sealed, and electrical connections can be made between the ends of the sense line (e.g., by inserting a conductive tab into the interface 152) at the time of sealing. However, bridging the unconnected ends of the sense line 140 across the interface 152 is not limited to the techniques disclosed herein, and can be done in any of a variety of ways. For example, in sealed, plastic-lined paper bag containers (e.g., for pet food), unconnected sections of the sense line can be connected through pads in the crimped end(s) of the bag across the width of the bag to ensure a change in state of the continuity sensor regardless of where the bag is opened.

In another embodiment, the sense line 140 may be formed on the container 150 by spray coating a transparent, conductive polymer instead of etching the sense line 140 from a blanket-deposited material. The conductive polymer material may be selected for its physical and/or electrical properties (e.g., a poly[3,4-ethylenedioxythiophene]:polystyrene sulfonate [PEDOT:PSS] copolymer). Spray coating may save approximately ⅔ of the material costs and eases the application of the sense line 140 to more complex shapes and/or patterns (e.g., to which a label, tape or other sense line substrate may not be easily applied). By using a conductive polymer, the sense line 140 may be invisible or nearly invisible, and can improve the appearance and/or aesthetics of the package (e.g., by avoiding use of a relatively large and/or shape-limited substrate). The cost relative to aluminum (e.g., blanket-deposited onto an applicable substrate) may be reduced by about ⅔, and the technique enables application or attachment of the sense line 140 on complex or complicated packaging/container shapes.

FIG. 4B shows the container 150 and sense line 140 of FIG. 4A with the exemplary smart security tag 100 thereon. The exemplary security tag 100 comprises a substrate 105 with an antenna 120, an integrated circuit 110, and a plurality of connection pads 130 and 132 thereon. The antenna 120 is electrically connected to the integrated circuit 110 in the same or substantially the same way as in FIGS. 1 and 2B. The sensing line 140 is electrically connected to the integrated circuit 110 through connection pads 130 and 132 (which are bonded to underlying sense line pads 142 and 144; see FIG. 4A). the inner and outer ends of the antenna 120 are connected by an electrical strap or trace on the opposite (inner) surface of the substrate 105 that is in contact with both of the antenna pads 125a-b.

As shown in part in FIG. 4B, the sensing line 140 extends over each of the separable or openable interfaces (e.g., 152) of the container 150. The sensing line 140 is connected to the integrated circuit 110 (and, in particular, to a continuity sensor in the integrated circuit 110) through the terminals 130 and 132. Opening the container 150 along the interface 152 (or the other interface on the opposite send of the container 150) as shown in FIG. 4C tears the sensing line 140 and changes the state of the continuity sensor in the integrated circuit 110. This results in a change in the continuity state of the container 150 (e.g., from “closed” or “sealed” to “open”).

Of course, the container 150 is not limited to a box with sealable, mated flaps at each of two opposite ends. For example, if the flap 155a is replaced with an extended flap 155b that functions as a lid for the container 150, and the opposite end of the container 150 is formed in a manner discouraging opening of that end, then the sense line 140 can be printed in a manner crossing the three separable interfaces between the flap 155b and the side panels of the container 150, and the security tag 100 can be placed on the flap 155b. Such an arrangement may be relatively easy to place on the inside surface of the container 150 (e.g., by printing the sense line on the flap 155b and parts of three side panels of the container 150).

In general, tearing a paper carton or other paper container is easier than tearing multiple layers of plastic. Thus, relative to a security tag in or on a laminated plastic label, the present security tag can be placed in any convenient location on or in a paper container as long as it is separated from the sense line. As a result, the present security tag provides more freedom to place the tag in a logistically or topologically better location (e.g., on a planar surface somewhere other than the location of the sense line).

The present security tags may be made and/or manufactured as described herein, except with a relatively short antenna (e.g., about ⅔ the length of an antenna configured to resonate at a standard RF, HF, UHF, VHF, etc. frequency) electrically connected to pads that can then be connected to the sense line (which effectively contributes the remainder of the antenna). A spray coating station for applying a conductive polymer to the package or container can spray a conductive polymer sense line (e.g., through a mask) onto the package or container to connect the sense line to the pads and cover the interface(s) between separable parts of the package or container to determine whether the package or container has been opened or not.

An Exemplary Alternative Security Tag with a Wireless Communication Device and Continuity Sensor on an Exemplary Multi-Compartment Container

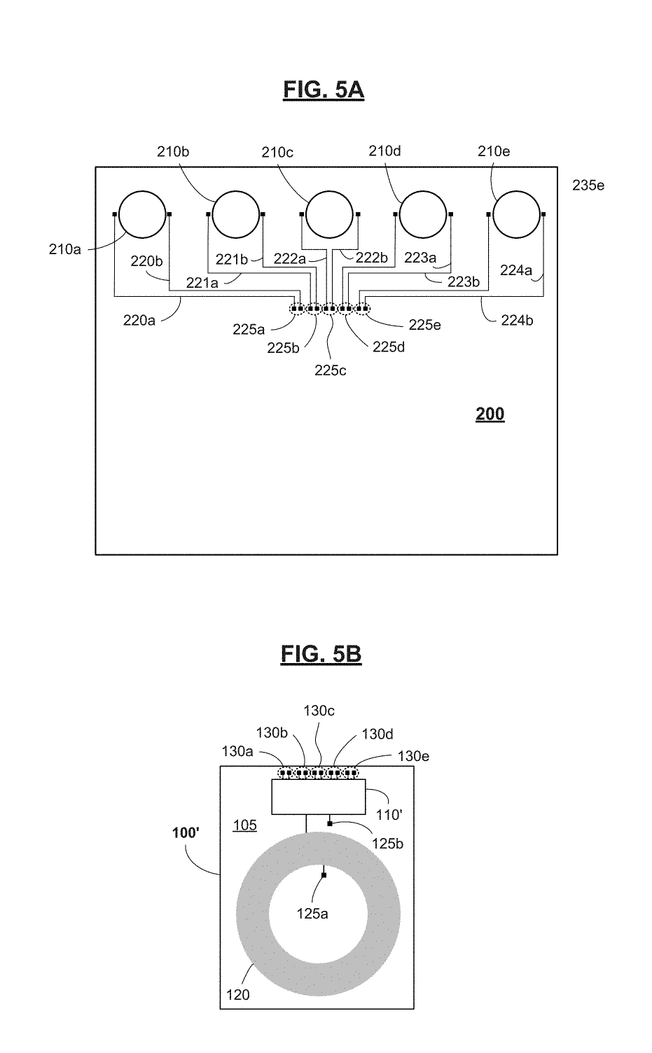

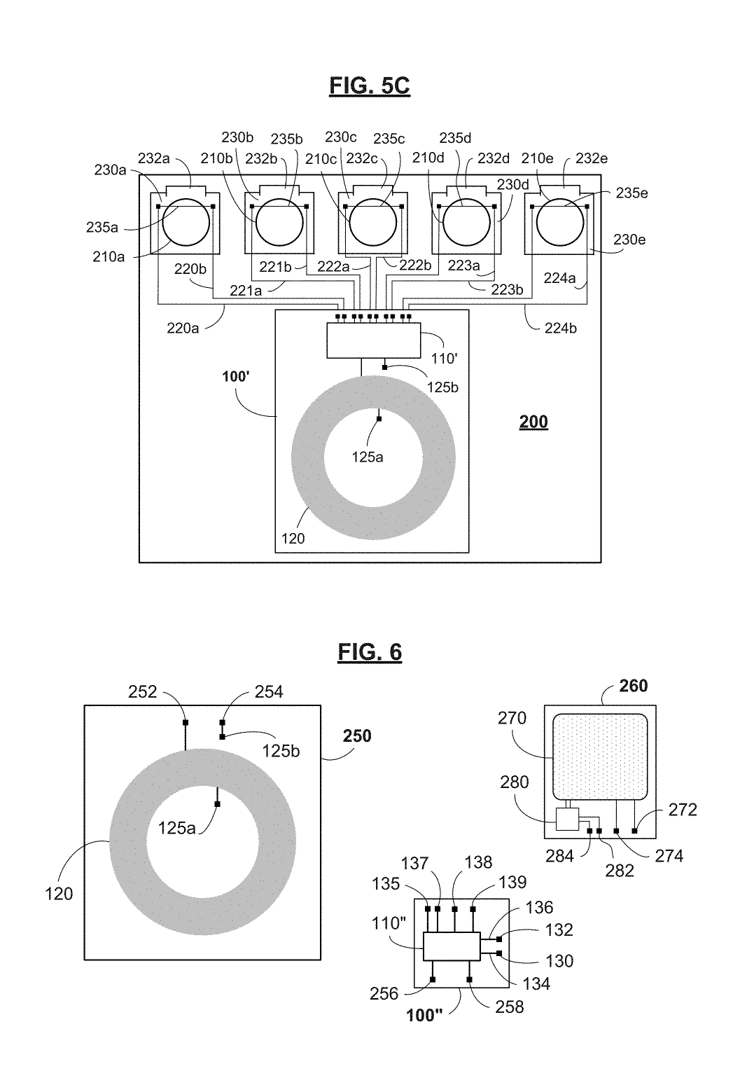

FIGS. 5A-C show an exemplary blister pack 200 and the present security tag 100′ in accordance with one or more embodiments of the present invention. Generally, the blister pack 200 includes a plurality of compartments or wells 210a-e in a tray or other surface. Although 5 compartments or wells 210a-e in a single row are shown, the invention is not limited to this number or arrangement. For example, the blister pack 200 may include any positive integer number of compartments or wells, in multiple rows (e.g., as a matrix with rows and columns, or with compartments or wells in adjacent rows offset from each other), in a circle or other geometric shape, as two or more concentric circles or other geometric shapes, etc. The blister pack 200 is particularly suited for various medicinal or pharmaceutical products that may be taken according to a schedule (e.g., once per day).

FIG. 5A shows the tray or upper surface of the blister pack 200, with traces 220a-224b thereon. The traces end in pairs of pads 225a-e, to which the security tag 100′ is electrically connected. Pairs of traces 220a-b, 221a-b, 222a-b, 223a-b and 224a-b respectively connect the pairs of pads 225a-e to pads on opposite sides of the respective compartments or wells 210a-e. The traces 220a-224b form portions of the sensing lines shown in FIG. 5C.

The security tag 100′ in FIG. 5B comprises a substrate 105 with an antenna 120, an integrated circuit 110′, and a plurality of connection pads 130a-e thereon. The antenna 120 and the connection pads 130a-e include traces that are electrically connected to the integrated circuit 110′ in the same or substantially the same way as the antenna 120 and traces shown in other FIGS. in this application. The inner end of the antenna 120 is connected to the integrated circuit 110′ using a strap (not shown) connecting antenna pads 125a-b in the same or substantially the same way as the antenna 120 in FIG. 1. The connection pads 130a-e electrically connect the integrated circuit 110′ to the traces 220a-224b, and thus, to the sensing lines.

FIG. 5C shows the completed blister pack 200, with the integrated circuit 110′ and a plurality of sealing flaps 230a-e thereon. Each of the compartments 210a-e are sealed or closed with a corresponding sealing flap 230a-e, respectively. Each of the sealing flaps 230a-e includes a respective sensing line portion or segment 235a-e thereon, extending over a unique and/or corresponding compartment 210a-e. Each sensing line portion or segment 235a-e electrically connects the pads on opposite sides of the respective compartments or wells 210a-e. for example, an adhesive conductive paste may be applied to one or both pairs of pads on the sensing line portion or segment 235a-e and/or the opposite sides of the compartments or wells 210a-e prior to sealing the compartments or wells 210a-e with the sealing flaps 230a-e. The sealing flaps 230a-e may also include tabs 232a-e, which may be configured to tear the corresponding sealing flap 230a-e across the corresponding sensing line segment 235a-e, and optionally, in a preferred tearing direction.

Thus, trace 220a, sensing line segment 235a and trace 220b form a sensing line that is connected to the integrated circuit 100′ (and, in general, to a unique continuity sensor in the integrated circuit 100′) through a pair of terminals 130a. Similarly, trace 221a, sensing line segment 235b and trace 221b form a sensing line that is connected to the integrated circuit 100′ through the pair of terminals 130b; trace 222a, sensing line segment 235c and trace 222b form a sensing line that is connected to the integrated circuit 100′ through the pair of terminals 130c; trace 223a, sensing line segment 235d and trace 223b form a sensing line that is connected to the integrated circuit 100′ through the pair of terminals 130d; and trace 224a, sensing line segment 235e and trace 224b form a sensing line that is connected to the integrated circuit 100′ through the pair of terminals 130e.

Upon pulling or lifting one of the tabs 232a-e, the corresponding sealing flap 230a-e tears, and as the corresponding compartment or well 210a-e is uncovered, the corresponding sensing line segment 235a-e is broken or otherwise severed. The open loop or circuit caused by breaking or severing the sensing line segment 235a-e causes a change of state in the corresponding continuity sensor in the integrated circuit 110′. The integrated circuit 110′ can then record which compartment or well 210a-e is opened, and optionally, the time at which the compartment or well 210a-e was opened.

Exemplary Connectable Electronic Modules or Units

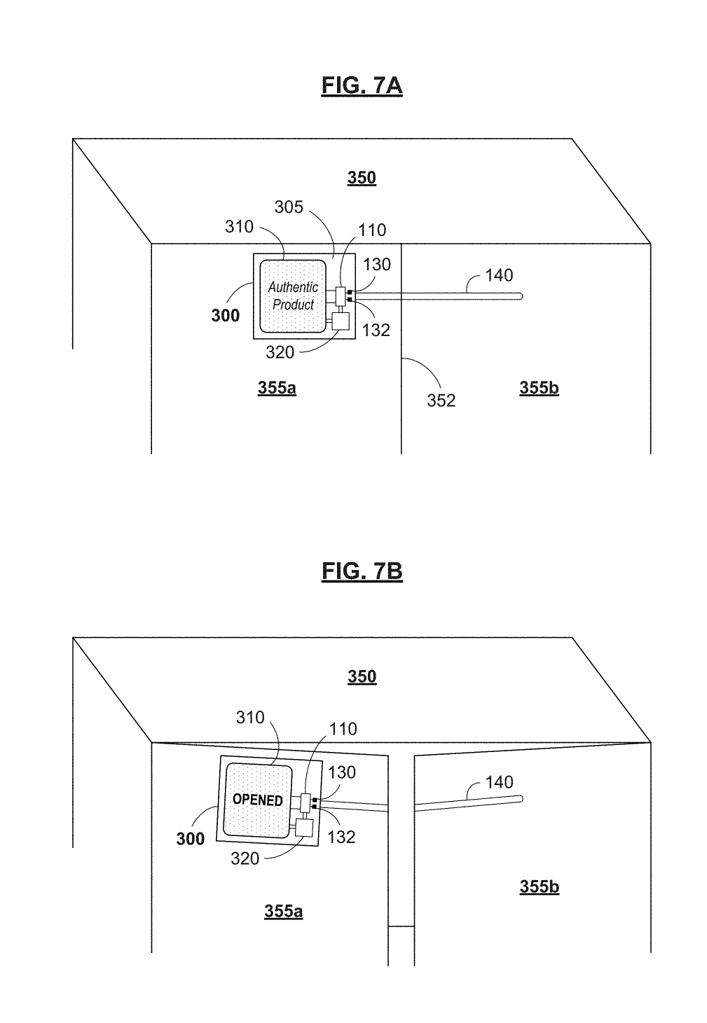

The present approach can be extended to connection of a printed and/or thin film integrated circuit to components other than sense lines. FIG. 6 shows an exemplary antenna module or unit 250, an exemplary printed and/or thin film integrated circuit module or unit 100″, and an exemplary display and battery module or unit 260. Each module or unit is on a separate substrate, and includes traces with connection pads for electrical connection to another module or unit. In general, the printed and/or thin film integrated circuit module or unit 100″ may be electrically connected to the antenna module or unit 250 and/or the display and battery module or unit 260.

For example, the integrated circuit module or unit 100″ includes an integrated circuit 110″ that is substantially the same as the integrated circuit 110 in FIGS. 1, 2A-B, 3A and 4B-C and the integrated circuit 110′ in FIGS. 5A-B, but when connected to and/or receiving power from a battery, the integrated circuit 110″ may not include power extraction circuitry, such as a rectifier. Furthermore, when connected to a display, the integrated circuit 110″ may not include a receiver, a transmitter, and/or other circuitry configured to process a wireless signal. In the embodiment shown in FIG. 6, the integrated circuit module or unit 100″ includes connection pads 135, 137, 138 and 139 for connection to the display and battery module or unit 260, and connection pads 256 and 258 for connection to the exemplary antenna module or unit 250. Connection pads 130 and 132 may be used to electrically connect the integrated circuit 110″ to another component, such as the sense line 140 (see, e.g., FIGS. 4A-B).

The antenna module or unit 250 includes an antenna 120, an electrical strap (not shown), strap pads 125a-b, and connection pads 252 and 254. The antenna 120 is the same or substantially the same as the antenna 120 in FIGS. 1, 2A-B, 3A, 4B-C and 5B-C. The connection pads 252 and 254 are for connecting the antenna 120 to the integrated circuit 110″ through the connection pads 256 and 258.

The display and battery module or unit 260 includes a display 270 and a battery 280. The display and battery module or unit 260 further includes connection pads 272 and 274 electrically connected to the display 270 (through traces on the substrate) and connection pads 282 and 284 electrically connected to the battery 280 (through additional traces on the substrate). The display 270 receives power from the battery 280. The connection pads 272 and 274 are for connecting the display 270 to the integrated circuit 110″ through the connection pads 138 and 139, and the connection pads 282 and 284 are for connecting the battery 280 to the integrated circuit 110″ through the connection pads 135 and 137. When connected, the display 270 can receive instructions and/or data from the integrated circuit 110″. In a further embodiment, the display 270 and the battery 280 are on separate substrates, which may further include one or more additional sets (e.g., pairs) of connection pads for forming an electrical connection between the display 270 and the battery 280.

The display 270 is, in some embodiments, relatively simple, and may comprise an electrochromic display (ECD), an electroluminescent display (ELD), a liquid crystal display (LCD), or a dot-matrix display. For example, the integrated circuit 110″ may send a simple “on/off” instruction (e.g., in the form of a binary logic signal) to the display 270. Alternatively, the display 270 may be relatively complex, and may comprise a thin film transistor liquid crystal display (TFT LCD), an organic light-emitting diode (OLED) display, electronic paper, a light-emitting diode (LED)-backlit LCD display, etc. Thus, a photoactive layer in the display 270 may comprise an electrochromic layer, an electroluminescent layer, a liquid crystal layer, or organic or inorganic LED layers, alone or in combination with a plurality of thin film transistors and/or LED backlighting, etc.

The battery 280 may be a conventional thin-film or printed battery, comprising a first current collector layer, a cathode, an electrolyte layer, an anode, and a second current collector layer. In general, the cathode is in electrical contact (and generally is in physical contact) with one of the first and second current collector layers, and the anode is in electrical contact (and generally is in physical contact) with the other of the first and second current collector layers. The electrolyte layer is between the cathode and the anode, and is generally in electrical and physical contact with each of the cathode and the anode.

In some embodiments, the battery is formed on a separate substrate and advantageously connected to one or more other components (e.g., the IC, the display, etc.) and/or activated at the latest possible time. For example, when the sense lines are printed on the package or container, one or more shunt lines (structurally similar or identical to the sense lines) that electrically connect the battery to the IC are also printed on the package or container. The battery can be formed on the same substrate as the IC (e.g., for convenience), but the battery circuit is not connected to the IC on the substrate. When the tag is attached to the sense lines, the substrate is placed on the package or container in a manner that connects the battery to the IC by the shunt lines. Thus, the battery shelf life can be extended (in some cases, significantly) because the battery is only connected when the IC and battery are placed on the package or container. This is especially significant when the battery has appreciable leakage or stand-by current (as is sometimes the case in printed electronics).

Other components on separate substrates may also be connected to the antenna module or unit 250, the integrated circuit module or unit 100″, and/or the display and battery module or unit 260. For example, an on/off switch (e.g., a dome switch) as described in U.S. Provisional Pat. Appl. No. 62/405,738 (Attorney Docket No. IDR4770-PR), the relevant portions of which are incorporated herein by reference. Additionally or alternatively, other sensors (e.g., in addition to the continuity sensor in the integrated circuit that is connected to a sense line) may be formed on a substrate separate from the integrated circuit module or unit 100″, and electrically connected to the integrated circuit 110″ through connection pads and traces as described herein.

An Exemplary Integrated Security Tag Including a Display

FIG. 7A shows an exemplary integrated security tag 300 including a display 310, an integrated circuit 110 and a battery 320 on a substrate 305. The security tag 300 is electrically connected to a sense line 140 on a container (e.g., box) 350. The display 310 may be the same or substantially the same as the display 270 in FIG. 6. The integrated circuit 110 may be the same or substantially the same as the integrated circuit 110″ in FIG. 6, the integrated circuit 110 in FIGS. 1, 2A-B, 3A and 4B-C, and/or the integrated circuit 110′ in FIGS. 5A-B, and is electrically connected to connection pads 130 and 132 through traces on the substrate 305. The battery 320 may be the same or substantially the same as the battery 280 in FIG. 6. The sense line 140 may be the same or substantially the same as the sense line 140 in FIGS. 3A and 4A-C, and may have ends connected to the connection pads 130 and 132. When the container 350 is packaged, the sense line 140 is electrically connected across the interface 352 between first and second separable container flaps 355a and 355b.

The display 310 may show the continuity state of the container 350 by displaying a text message or other visual indication, such as “Authentic Product” when the container 350 remains sealed from the time of factory production or packaging. The display 310 may also show other information about the product or the conditions under which the product was shipped and/or stored, a message from the manufacturer or reseller, etc.

In some embodiments, the integrated security tag 300 may further comprise an antenna (not shown), and the integrated circuit 110 may be further configured to process wireless signals to or from a reader (e.g., an RF- or NFC-enabled smart phone or tablet computer). In such embodiments, the manufacturer and/or reseller may send a message or other information to the consumer depending on the continuity state of the container 350. For example, when the continuity state of the container 350 is sealed (or its equivalent), the manufacturer and/or reseller may send product price information and/or information about other products with which the product in the container 350 may be advantageously used. On the other hand, when the continuity state of the container 350 is opened, the manufacturer and/or reseller may send use information for the product, such as instructions for assembly or use, recipes (for food or beverage products), etc. In a further embodiment, the display 310 may further comprise a touch screen to enable the user to input information or data to send to manufacturer or reseller.

FIG. 7B shows the container 350 after it has been opened and the sensing line 140 has been severed or broken. In such a case, the display 310 may show a different continuity state of the container 350 by displaying a text message or other visual indication, such as “OPENED” when the container 350 is opened and the sensing line 140 severed or broken.

An Exemplary Integrated Circuit

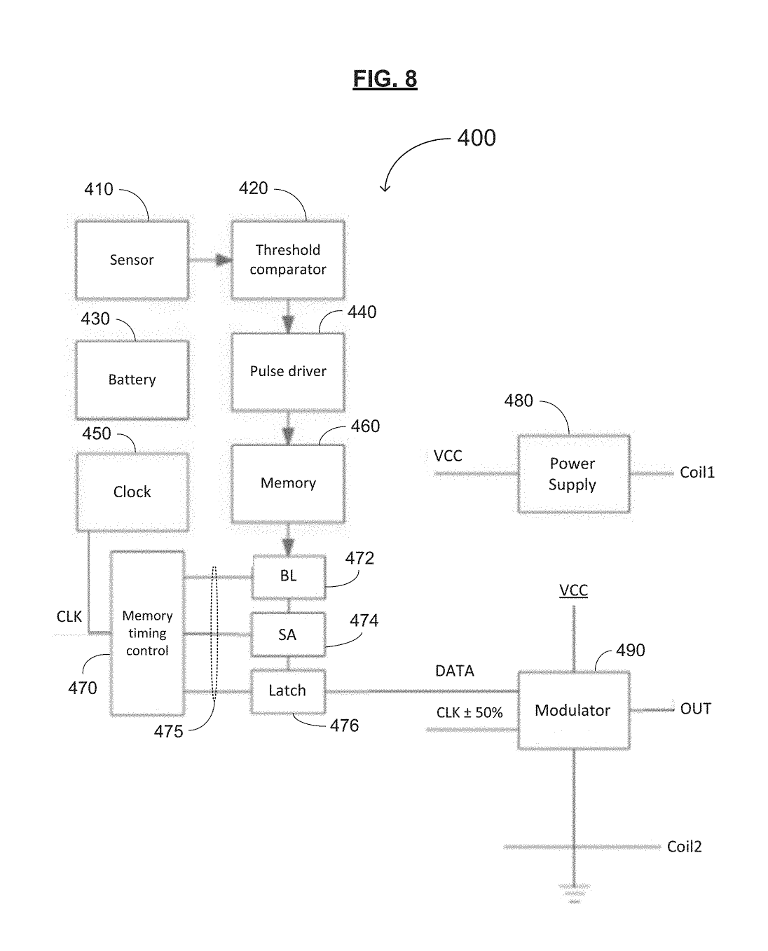

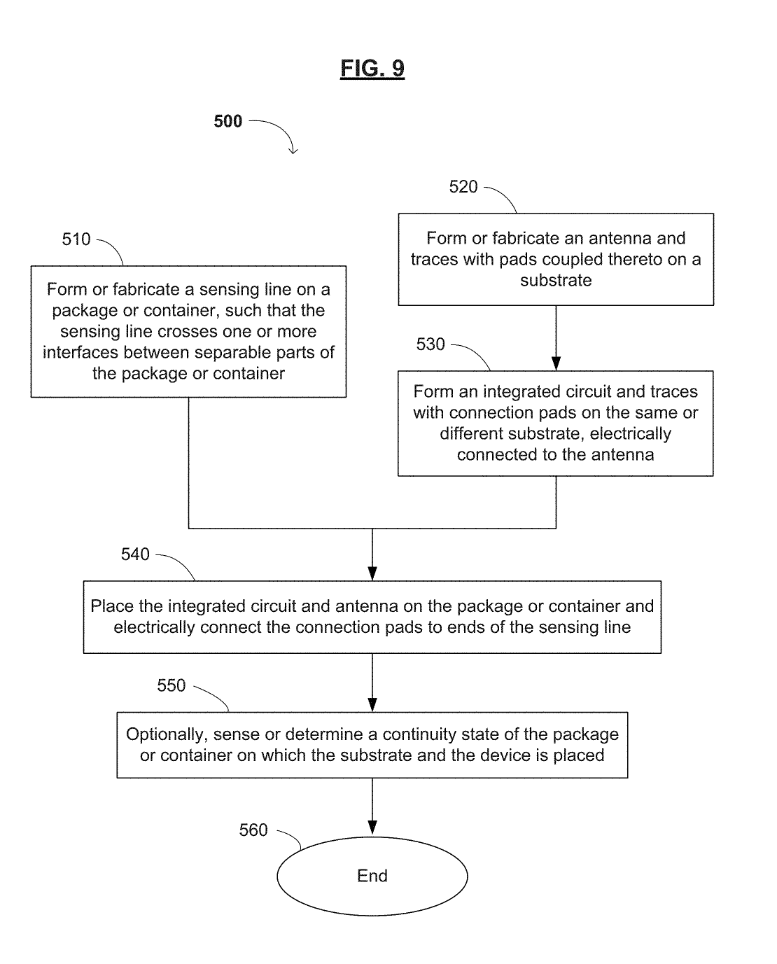

FIG. 8 shows an exemplary integrated circuit 400 for use in the present wireless security or ID device. Some or all of the circuit and/or functional blocks in the exemplary integrated circuit 400 can be present in the integrated circuit 110 in FIGS. 1, 2A-B, 3A, 4B-C and 7A-B, the integrated circuit 110′ in FIGS. 5A-B and/or the integrated circuit 110″ in FIG. 6. Additional circuit blocks, such as one or more display drivers, can also be included in certain embodiments.

The exemplary integrated circuit (IC) 400 for use with the present security or ID tag includes one or more sensors 410, a threshold comparator 420 receiving information (e.g., a signal) from the sensor(s) 410, a pulse driver 440 receiving an output of the threshold comparator 420, a memory 460 storing sensor data from the pulse driver 440, one or more bit lines (BL) 472 for reading data from the memory 460, one or more sense amplifiers (SA) 474 for converting the signal(s) on the bit line(s) to digital signals, one or more latches 476 for temporarily storing data from the sense amplifier(s), and a transmitter (e.g., modulator) 490 configured to output data (including an identification code) from the device. The exemplary IC 400 in FIG. 7 also contains a clock 450 configured to provide a timing signal (e.g., CLK) that controls the timing of certain operations in the IC 400 and a memory timing control block or circuit 470 that controls the timing of memory read operations. The modulator 490 also receives the timing signal (CLK) from the clock circuit or a slowed-down or sped-up variation thereof. The exemplary IC 400 also includes a power supply block or circuit 480 that provides a direct current (e.g., VCC) to various circuits and/or circuit blocks in the IC. The memory 460 may also contain identification code. The portion of the memory 460 containing identification code may be printed. The IC 400 may further contain a receiver (e.g., a demodulator), one or more rectifiers (e.g., a rectifying diode, one or more half-bridge or full-bridge rectifiers, etc.), one or more tuning or storage capacitors, etc. Terminals in the modulator 490 and the power supply 480 may be connected to ends of an antenna (e.g., at Coil1 and Coil2). Alternatively, the modulator may be omitted or replaced with one or more display drivers, for example, and the power supply 480 may be connected to one or more leads electrically connected to a battery and optionally a ground plane or other ground potential.

The memory in an NFC or RF identification device may contain a fixed number of bits. In some implementations, NFC tags may contain 128 or 256 bits. Some bits are allocated to overhead (non-payload) data for format identification and data integrity (CRC) checking. The payload of the device (e.g., the NFC or RF tag) consumes the remainder of the bits. For example, the payload can be up to 96 bits in the case of the 128-bit NFC tag and up to 224 bits in the case of the 256-bit NFC tag.

The payload of the NFC tag can be allocated to variable amounts of fixed ROM bits (which are generally—but not always—used as a unique identification number). When print methods are used in manufacturing the NFC tag, the ROM bits are permanently encoded and cannot be electrically modified. Any payload bits that are not allocated as fixed ROM bits can be allocated as dynamic sensor bits (e.g., for the continuity sensor to which the sensing lines are connected). These sensor bits can change values, based on a sensed input. Different splits or allocations between ROM and sensor bits are indicated by data format bits that are part of the non-payload or ‘overhead’ bits, generally in the first 16 bits of the NFC tag memory.

One example of how continuity sensing may be implemented in the present invention involves a sensor 410 that detects when a sensing line (e.g., sensing line 140 in FIGS. 3A, 4A-C and 7A-B) is broken. Upon such an event, one or more sensor bits in the memory 460 change state to reflect the broken or cut sensing line. This indicates to the reader (e.g., an NFC smartphone, etc.) that the protected container has been opened. The ROM ID bits do not change, but any data integrity bits (e.g., for CRC) may be updated to reflect the state of the sensor bits.

Continuity sensing generally refers to a capability and/or function that senses or determines whether a container has been tampered with or opened on the one hand, or remains in a closed state (e.g., its factory-sealed condition) on the other hand. In one embodiment, continuity sensing is implemented using at least one sensing line (e.g., sensing line 140 in FIGS. 3A, 4A-C and 7A-B). The present security device may be thought of as having two parts: a first part that includes the IC and the antenna (or display), and a second part that includes the sensing line(s). The part of the wireless security device that includes the IC and antenna or display is on a first part of the protected container. The part of the security device that includes the sensing line(s) may be on the same part of the container as the integrated circuit and the antenna or display, or may be at least partially on a second, separable part of the protected container and/or a sealing device or mechanism such as a cap or lid that may move relative to the container (e.g., a bottle, jar or tray) upon opening. The sensing line may cross an interface between the two separable parts of the container. Opening the container or packaging along or across the interface generally breaks the sensing line.

In addition to a primary sensing line, the present wireless security device may include one or more redundant sensing lines. The redundant sensing line(s) can be used in an “AND”-type function with the primary sensing line(s) (e.g., the IC and sensor sense that the container or packaging is opened only when all of the primary and redundant sensing lines are broken), or in an “OR”-type function with the sensing line(s) (e.g., the IC and sensor sense that the container or packaging is opened or has been tampered with when any of the primary and redundant sensing lines are broken). Alternatively, the sensing line and redundant sensing lines can provide one or more “partially-opened” continuity states when one or more of the primary and redundant sensing lines are broken and one or more of the primary and redundant sensing lines are not broken. One skilled in the art can easily derive logic and applications for such functionality and/or capability.

Of course, the IC 400 in the present device may include one or more other sensors in addition to the continuity sensor(s). For example, the IC 400 can further include one or more temperature sensors, humidity sensors, electromagnetic field sensors, current/voltage/power sensors, light sensors, and/or chemical sensors (e.g., for oxygen, carbon monoxide, carbon dioxide, nitrogen oxides, sulfur dioxide and/or trioxide, ozone, one or more toxins, etc.). The present IC may also include one or more time sensors (e.g., configured to count or determine elapsed time), which may include the clock circuit (which can be a basis for a real-time clock) and one or more counters, dividers, etc., as is known in the art. The leads from any external sensing mechanism should be connected to the IC at terminals separate from those for the antenna and the continuity sensor. Such sensors may be on the same substrate as the antenna and the IC, or on a different substrate that is electrically connectable to the antenna and/or the IC (see, e.g., FIG. 6).

An Exemplary Method of Making and Applying a Security Tag Having a Continuity Sensor Therein to a Package or Container and Sensing a Continuity State of the Package or Container

The present invention also concerns one or more methods of making and applying a security tag or device having a continuity sensor therein to a package or container and/or sensing a continuity state of the package or container that includes forming a sensing line on the substrate, forming an integrated circuit on a substrate, forming one or more additional components (such as an antenna, a display and/or a battery) on the same substrate or on one or more different substrates, and electrically connecting (i) the additional component(s) to the integrated circuit, and (ii) the sensing line to a set of connection pads electrically connected to the integrated circuit. The sensing line crosses one or more interfaces between separable parts of the package or container, and is therefore configured to sense or determine a continuity state of a package or container on which the security tag or device is placed or to which the security tag or device is fixed or adhered.

FIG. 9 shows a flow chart for an exemplary method 500 of applying a security tag or device (e.g., an NFC and/or RFID tag) having a continuity sensor therein to a package or container and sensing a continuity state of the package or container in accordance with one or more embodiments of the present invention. The present method advantageously enables manufacture of a universal or standard integrated circuit with a continuity sensor therein that can be electrically connected to an antenna or other communication mechanism (which can be made in a standardized way) and one or more sense lines that can be customized for a package or container in accordance with the dimensions, design and/or materials of the package or container.

At 510, a sensing line may be formed or fabricated on a package or container. The sensing line crosses one or more (and preferably all) of the interfaces between separable or openable parts of the package or container. In various embodiments, the separable or openable parts of the package or container include sealable flaps in or on a box, a lid (hinged or unhinged) on a box or tray, a cap on a bottle or jar, a cork in a bottle, a flap on an envelope, a plastic or paper seal over a well in a plastic container or tray, etc. The sensing line may be formed as described herein, and may include extra material deposited or printed on or at the interface, or a connection tab inserted into the interface where the sections of the sensing line meet.

Separately, at 520, an antenna is formed or fabricated on a surface of a substrate. The antenna may be configured to receive and/or transmit or broadcast a wireless signal. In some embodiments, forming the antenna may consist of forming a single metal layer on the substrate, and etching the single metal layer to form the antenna. In other embodiments, forming the antenna may comprise printing a metal ink on the substrate in a first pattern corresponding to the antenna. Printing may include screen printing, inkjet printing, gravure printing, roll-to-roll printing, etc.

Alternatively, the security device may include a display and a battery instead of (or in addition to) an antenna. The display may be made conventionally on a separate substrate, for example by printing, thin film processing, roll-to-roll processing, a combination thereof, etc. Similarly, the battery may be made conventionally on the same substrate as the display or on a separate substrate. Similar to the antenna, the battery may be formed by printing, thin film processing, roll-to-roll processing, a combination thereof, etc. If made on a separate substrate, the battery may be attached to the display substrate (or other substrate, such as that on which the integrated circuit is formed) using surface mount technology (SMT) equipment and/or processing.

Forming the display may comprise forming a first electrode on the substrate, forming a photoactive layer thereon, and forming a second electrode on the photoactive layer. Forming the display may further comprise forming a transparent window over the electrodes and photoactive layer, if necessary (e.g., the display is not formed on a transparent substrate or a substrate having a transparent window therein). At least one of the first and second electrodes may be transparent.

In addition, forming the battery may comprise forming a first current collector layer on the same substrate or a separate substrate, a cathode or anode thereon, an electrolyte layer on the cathode or anode, the other of the cathode or anode on the electrolyte layer, and a second current collector layer on the other of the cathode or anode. A sealant layer may be formed over the entire battery after all other layers are formed.

At 530, an integrated circuit may be formed on the same or different substrate as the antenna (or, alternatively, the display and/or battery). Forming the integrated circuit may comprise printing one or more layers of the integrated circuit, and processing the remainder of the integrated circuit by thin film processing techniques. Alternatively, all layers of the integrated circuit may be printed. Printing offers advantages over photolithographic patterning processes, such as low equipment costs, greater throughput, reduced waste (and thus, a “greener” manufacturing process), etc., and can be ideal for relatively low transistor-count devices such as near field, RFID, security and other tags. Furthermore, one or more layers of the integrated circuit may be printed using roll-to-roll processing.

Alternatively, the method may form all layers of the integrated circuit by one or more thin film processing techniques. Thin film processing also has a relatively low cost of ownership, and is a relatively mature technology, which can result in reasonably reliable devices being manufactured on a wide variety of potential substrates, including a machine direction oriented (MDO) film (which may have a preferential tearing direction). In some embodiments, the best of both approaches can be used, and the method may form one or more layers of the integrated circuit by one or more thin film processing techniques, and printing one or more additional layers of the integrated circuit.

The integrated circuit may be formed on a separate substrate and attached to the substrate on which the antenna (or the display and/or battery) is formed (e.g., by pick-and-place [surface mount] technology and/or processing), or directly on the same substrate. The integrated circuit may be formed before or after the antenna or the display and/or battery. Regardless of whether the integrated circuit is formed before or after the antenna, terminals are formed in the integrated circuit in electrical contact with ends of the antenna, or connection pads are formed on the integrated circuit substrate to which the ends of the antenna are electrically connected. Thus, the integrated circuit may have a first set of connection pads electrically connected to the antenna. Alternatively, the integrated circuit may have a second set of connection pads electrically connected to the display and/or a third of connection pads electrically connected to the battery. Additional sets of connection pads may be formed for electrical connection to additional components, such as an on/off switch or an additional sensor.

At 540, the integrated circuit and antenna (or display and battery) are placed on the package or container, typically in positions that enable formation of an electrical connection between the integrated circuit connection pads and the ends of the sensing line. Placing the substrate on the package or container may include adhering or wiping the substrate onto the package or container manually, semi-automatically, and/or automatically. Additionally, pressure and/or heat may be applied to the substrate to assist with adhering the substrate to the package or container. Subsequently, the substrate may be further secured to the package or container with shrink wrap or plastic wrap, or if the container is a bottle, a spinner and/or a capsule.

The sensing line is electrically connected to the integrated circuit via the connection pads on the integrated circuit substrate, as described herein. For example, a conductive adhesive may be applied (e.g., by printing, coating, spraying, etc.) to the connection pads and/or to the ends of the sensing line prior to placing the integrated circuit and antenna (or display and battery) on the package or container.

At 550, a continuity state of the package or container that the security device is placed on or over may be sensed or determined using the communication (e.g., NFC and/or RF) device. The exemplary method of manufacturing the communication (e.g., NFC and/or RF) device(s) in accordance with one or more embodiments of the present invention is complete at 560.

Thus, the present invention may concern a method of determining a continuity state of a package or container. The method includes forming a sensing line on first and second separable parts of the package or container and over an interface between the first and second separable parts of the package or container, and using the integrated circuit, sensing a continuity state of the package or container. The integrated circuit may be electrically connected to an antenna or to a display and battery. The sensing line is configured to sense or determine a continuity state of a package or container on which the security device is placed or to which the security device is fixed or adhered.

In some embodiments, the security device is a wireless security device (e.g., a near field and/or radio frequency security device). In such embodiments, the continuity state of the package or container is sensed by reading the wireless security device with an enabled reader (e.g., an NFC- or RF-enabled smart phone or tablet computer), and displaying the continuity state on the display of the reader. Alternatively, the security device includes a display, and the continuity state of the package or container is sensed by the continuity sensor in the integrated circuit, then displayed on the display.

### CONCLUSION

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A security and/or identification device, comprising:
a) a first substrate configured to be applied, affixed or attached to a package or container;
b) an integrated circuit on the first substrate, including (i) a first set of connection pads electrically connected to the integrated circuit and configured to be electrically connected to a first component external to the integrated circuit and the first substrate, and (ii) a memory storing a unique identification number for the security and/or identification device; and
c) a second component selected from an antenna and a battery on the first substrate or a second substrate, the antenna being configured to (i) receive a first wireless signal and optionally transmit or broadcast a second wireless signal and (ii) when the battery is absent, enable the integrated circuit to extract power from the first wireless signal, and the battery providing power to the integrated circuit.

2. The security and/or identification device of claim 1, wherein the integrated circuit comprises a continuity sensor electrically connected or coupled to the first set of connection pads, configured to determine a continuity state of the package or container, and the memory includes one or more bits configured to store a value corresponding to the continuity state of the container or package.

3. The security and/or identification device of claim 2, wherein the integrated circuit further comprises one or more additional sets of connection pads electrically connected to the integrated circuit, and the first set of connection pads and the one or more additional sets of connection pads are configured to be electrically connected or coupled to a plurality of sensing lines.

4. The security and/or identification device of claim 1, wherein the second component comprises the antenna.

5. The security and/or identification device of claim 1, wherein the second component comprises the battery.

6. The security and/or identification device of claim 5, further comprising a display on the first substrate, the second substrate or a third substrate, wherein the display is electrically connected to the battery and the integrated circuit, and the integrated circuit is configured to provide data and/or one or more instructions to the display.

7. The security and/or identification device of claim 1, further comprising an adhesive on the first substrate.

8. The security and/or identification device of claim 1, further comprising a pressure-sensitive adhesive or a heat-activated conductive adhesive on the first set of connection pads.

9. The security and/or identification device of claim 1, comprising a near field and/or radio frequency security and/or identification device.

10. The security and/or identification device of claim 1, wherein the integrated circuit comprises one or more printed layers.

11. The security and/or identification device of claim 1, wherein the substrate comprises a plastic or a metal foil, is flexible, and can withstand a processing temperature of up to 200° C.

12. A method of manufacturing a security and/or identification device, comprising:
a) forming an integrated circuit on a first substrate configured to be applied, affixed or attached to a package or container, the integrated circuit including (i) a first set of connection pads electrically connected to the integrated circuit and configured to be electrically connected to a first component external to the integrated circuit and the first substrate, and (ii) a memory storing a unique identification number for the security and/or identification device; and
b) forming a second component selected from an antenna and a battery on the first substrate or a second substrate, the antenna being configured to (i) receive a first wireless signal and optionally transmit or broadcast a second wireless signal and (ii) when the battery is absent, enable the integrated circuit to extract power from the first wireless signal, and the battery providing power to the integrated circuit.

13. The method of claim 12, wherein the integrated circuit comprises a continuity sensor electrically connected or coupled to the first set of connection pads, the continuity sensor being configured to determine a continuity state of the package or container, and the memory includes one or more bits configured to store a value corresponding to the continuity state of the container or package.

14. The method of claim 13, wherein the integrated circuit further comprises one or more additional sets of connection pads electrically connected to the integrated circuit and configured to be electrically connected or coupled to a plurality of the sensing lines.

15. The method of claim 12, wherein the second component comprises the antenna.

16. The method of claim 12, wherein the second component comprises the battery.

17. The method of claim 12, further comprising depositing an adhesive on the first substrate.

18. The method of claim 12, wherein the security and/or identification device is a near field and/or radio frequency device.

19. The method of claim 12, wherein forming the integrated circuit comprises printing one or more layers of the integrated circuit.

20. The method of claim 12, wherein the first substrate comprises a plastic or a metal foil, is flexible, and can withstand a processing temperature of up to 200° C.
